(19) United States
(12) Patent Application Publication
(10) Pub. No.: US 2014/0358457 A1
(43) Pub. Date: Dec. 4, 2014

(54) METHOD AND APPARATUS FOR CONTINUOUS PROCESSING OF AN ELECTROMAGNETIC POWER MEASUREMENT

(71) Applicant: Wireless Telecom Group, Inc., Parsippany, NJ (US)

(72) Inventor: Ronald SWANSON, Morris Plains, NJ (US)

(73) Assignee: Wireless Telecom Group, Inc., Parsippany, NJ (US)

(21) Appl. No.: 14/295,739

(22) Filed: Jun. 4, 2014

Related U.S. Application Data
(60) Provisional application No. 61/831,113, filed on Jun. 4, 2013.

(51) Int. Cl. G01R 21/133

(52) U.S. Cl. CPC G01R 21/133
USPC 702/60

(57) ABSTRACT

This disclosure relates to receiving an electromagnetic signal by a power detector, converting the received electromagnetic signal into a plurality of digitized samples, continuously acquiring and storing the plurality of digitized samples of into one or more sample memory buffers based upon a plurality of power processing events, simultaneously reading out of the one or more sample memory buffers the stored plurality of digitized samples, linearizing the plurality of digitized samples, wherein linearizing comprises converting the plurality of digitized samples into a plurality of linear power units such that the linear power units represent power measurements based upon the plurality of power processing events, and trace averaging the plurality of linear power units, wherein the simultaneously reading out of the one or more sample memory buffers, linearizing, and trace averaging are pipeline processed.

### CROSS REFERENCE TO RELATED APPLICATIONS

This application claims priority to U.S. Provisional Patent Application No. 61/831,113 filed on Jun. 4, 2013. The disclosure of the U.S. Provisional Patent Application 61/831,113 is hereby incorporated by reference.

### BACKGROUND INFORMATION

Universal serial bus (USB) radio frequency power sensors, also known as USB power meters (hereinafter “USB power sensors”), have in recent years become more pervasive due to their portability and lower cost compared to traditional bench top models. USB power sensors perform a variety of measurements on electromagnetic signals emanating from radio frequency (RF) and microwave communication devices and systems, including peak power and average power measurements. Peak power, sometimes referred to as “pulse profiling,” provides a measurement of the energy flow in every pulse or a measurement of power versus time. Average power measurement provides a single number average of the rate of flow of energy over a full period of time, sometimes referred to as the heating effect of the signal. Additional measurements can be derived by USB power sensors such as peak-to-average ratio, rise time, fall time, maximum power and minimum power measurements, and USB sensors also can provide statistical data regarding wideband signals.

Digital modulation methods are employed by 3G and 4G cellular communications systems and microwave communication systems, as well as other broadband wireless communication systems. Some examples of digital modulation methods include phase shift keying (PSK), minimum shift keying (MSK), quadrature amplitude modulation (QAM), quadrature phase shift keying (QPSK), and binary phase shift keying (BPSK). These digital modulation techniques, together with multiplexing techniques (e.g., time division multiple access (TDMA), code division multiple access (CDMA) and recently demand assigned multiple access (DAMA)), present a challenge for making accurate peak power measurements. For example, Long term evolution (LTE) and LTE-Advanced employ orthogonal frequency-division multiplexing (OFDM) where OFDM data is distributed over a large number of closely spaced orthogonal subcarriers (e.g., two subcarriers are orthogonal if the maximum amplitude of one subcarrier is reached while the other subcarriers amplitude is zero). Each subcarrier is modulated using varying levels of modulation (e.g., QPSK or QAM) depending on the signal quality. LTE/LTE-A category 5 user equipment can support up to 64 QAM. WiMax and IEEE 801.16 mobile stations are also capable of supporting 64 QAM. Global system for mobile communications (GSM), general packet radio services (GPRS) and enhanced data for GSM evolution (EDGE) mobile devices can support 32 QAM. Enhanced functionality of EDGE called voice services over adaptive multi-user channels on one slot (VAMOS) employs a new modulation scheme called adaptive-QPSK (AQPSK) in downlink communications.

Another significant challenge to conventional power sensors is the processing of wide video bandwidth signals. Video (VBW) bandwidth refers to the bandwidth of the amplitude envelope fluctuations without regard to frequency or phase spectral content. When wide VBW, spread-spectrum signals such as those employed by CDMA or LTE are viewed in the time domain, there are many envelope peaks. The VBW affects the general width of these peaks (e.g., wider VBW yields narrower peaks), and the coding method determines how frequently various peak levels occur. However, conventional power sensors only capture a small portion of the wide VBW signals due to lengthy acquisition gaps caused by conventional power processing techniques. Accordingly, conventional power sensors miss many peaks that might be important for characterizing the wide VBW signal.

Conventional peak power sensors digitize the detected RF signal at a high sample rate and store the digitized samples into a first in first out (FIFO) multi-byte memory or other memory buffer. A predetermined event or point of interest is selected to start the sampling of data which continues until the FIFO or memory buffer contains enough samples to complete the sweep. An event or point of interest identifies an event or point of interest in the acquired data, and is used to synchronize the presentation of this data to facilitate the desired time-domain view. Then acquisition of the samples halts so a microprocessor or digital signal processor (DSP) can process the raw samples into a trigger-synchronous trace buffer. Further statistical or waveform analysis may follow, as well as periodic scaling of the sweep data and measurement data to dBm or watts. The scaled sweep data and measurement data are then transmitted to a host such as a personal computer (PC) for display and additional analysis.

The above described steps of sampling, acquisition and scaling (“sweep processing sequence”) by conventional peak power sensors typically must take place sequentially. Moreover, a new sweep to acquire a new sample acquisition cannot commence until the microcontroller or DSP has completed most or all of the steps in the current sweep processing sequence. This results in acquisition gaps during which time no data is gathered and the trigger cannot be re-armed. The re-arming time can be further extended in a scenario where pre-triggered measurements are required. These delays in re-arming have significant consequences. For example, if the pulse repetition interval (PRI) of a periodic signal is shorter than the sweep's measurement cycle time, then one or more pulses will occur before the trigger re-arms, and points of interest will be missed. If trace averaging and/or multi-sweep envelope accumulation is also enabled significant and frustrating delays will be caused by the need to acquire an adequate number of sweeps to fulfill the averaging or accumulation criteria. Moreover, a conventional power sensor will likely miss a single transient, which might occur over several hours monitoring.

Accordingly, there is a need for a method, device and computer program for providing fast and meaningful power measurements which overcomes the above-described deficiencies (e.g., significant delays in data acquisition and loss of data) among conventional peak power sensors.

The foregoing and other aspects of the example embodiments of this invention are further explained in the following Detailed Description, when read in conjunction with the attached Drawing Figures.

### BRIEF DESCRIPTION OF THE DRAWINGS

FIG. 1 is a schematic block diagram of a power meter configured for real time power processing in accordance with example embodiments of the present invention;

FIG. 2 is a schematic block diagram of a linearizer for real-time power processing in accordance with example embodiments of the invention;

FIG. 3 depicts a timing diagram showing a pipeline process adapted for real-time power processing in accordance with example embodiments of the present invention;

FIG. 4 is a schematic block diagram of a pre-averager configured for real time power processing in accordance with example embodiments of the present invention;

FIG. 5 depicts a synchronous trace filter adapted for averaging or overwriting trigger-synchronized linearized data currently present in the trace buffer with trigger-synchronized linearized data from the pre-averager in accordance with example embodiments of the invention;

FIG. 6 depicts a synchronous trace filter adapted for detecting and storing minimum and maximum values identified by comparing trigger-synchronized linearized data from the pre-averager with trigger-synchronized linearized data currently present in the trace buffer in accordance with example embodiments of the invention.

FIG. 7 depicts a power sensor enclosure in accordance with example embodiments of the invention; and

FIG. 8 is a logical flow diagram of the operation of methods and execution of computer program instructions tangibly embodied on a computer readable memory or field programmable gate array adapted to provide real-time power processing in accordance with example embodiments of the present invention.

### DETAILED DESCRIPTION

The example embodiments of this invention provide apparatuses, methods, and computer programs that receive an electromagnetic signal by a power detector, convert the electromagnetic signal into a plurality of digitized samples, continuously acquire and store the plurality of digitized samples of the electromagnetic signal into one or more sample memory buffers based upon a plurality of power processing events, simultaneously reading out of the memory buffers the stored digitized samples by a linearizer adapted for converting the digitized samples into a plurality of linear power units based upon the plurality of power processing events, and trace averaging the plurality of linear power units, wherein simultaneously reading out of the one or more sample memory buffers, linearizing, and trace averaging are pipeline processed.

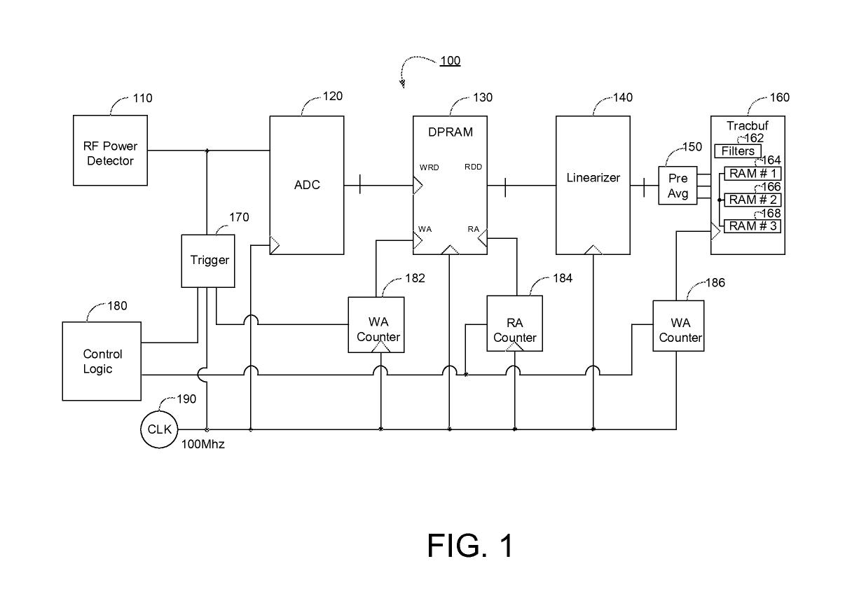

FIG. 1 is a schematic block diagram of a power meter 100 configured for real time power processing in accordance with example embodiments of the present invention. As shown in FIG. 1, the power meter 100 includes a power detector 110 adapted for receiving an electromagnetic signal from a radiating device and which is suitable for converting the electromagnetic signal to dc signal. In one example embodiment, power detector 110 is a diode detector (e.g., set at low power and in its square-law response region or set to a peak detecting region) coupled to a linear amplifier. In another example embodiment, the power detector 110 is a diode detector (e.g., set at low power and in its square-law response region or set to a peak detecting region) coupled a logarithm amplifier. In yet another example embodiment, power detector 110 is an integrated detector integrated circuit (IC), which feeds the electromagnetic signal into the IC. In all embodiments, power detector 110 may optionally contain amplification or signal-conditioning buffer circuitry. The output voltage from the power detector 110 is characterized as a non-linear, a monotonic function of (nearly) instantaneous incident electromagnetic power due to the detection and amplification processes.

The power detector 110 is coupled to a high speed analog-to-digital-convertor (ADC) 120 as shown in FIG. 1. In one example embodiment, ADC 120 is adapted for 14 bit resolution with a 100 mega sample per second (MSPS) input clocked at 100 MHz as set by sample clock 190 (which also functions as a system clock). In another example embodiment, the bit resolution can be greater than or less than 14 bits and the clock speed can exceed several hundred MHz (e.g., 200 MHz to 250 MHz).

The digital stream of data output from ADC 120 is fed into a dual-port circular memory buffer such as dual port read only memory (DPRAM) 130. In one example embodiment DPRAM 130 is one or more internal or external memory devices or embedded Block RAMs (BRAMs). For example, referring to FIG. 7, DPRAM can be within power sensor enclosure 710 or located remotely on a personal computing device by way of USB 740. In an alternative example embodiment, DPRAM 130 is replaced by a field-programmable gate array (FPGA) where the digital data stream is stored in logic blocks within the FPGA.

In one non-limiting example embodiment, DPRAM 130 can hold 1.2 ms of data (128k×14) before the buffer fills. As will be explained in more detail below, the stored digital data stream is processed in real-time taking advantage of DPRAM's circular addressing, where both the read and write address are known and controlled. As such, example embodiments allow a 1.2 ms look-back period which is enough data storage to save pre-trigger information. That is the entire sweep worth of samples need not be stored in DPRAM 130 as simultaneous real-time power processing of digital data stream reads data out of DPRAM as soon as a trigger occurs which keeps pace with incoming new data. Larger or smaller size logic block arrays can be employed depending upon the clock speed and size of the digital stream of data output to be stored (e.g., allowing larger or smaller look-back periods).

As shown in FIG. 1, a write address counter 182 and read address counter 184 are coupled to a write address port and to a read address port on DPRAM 130 adapted to control the write/read function of that memory based upon a trigger event stored in trigger unit 170 (e.g., arms and re-arms the acquisition/process of data samples based upon a trigger event). A trigger event is a point of interest or event which can be, for example, a sample index and time location (e.g., the fine position) which detected the leading edge of a pulse signal, or a gate-start/end-time as set by a timing gate of a particular domain of interest stored in memory and as known to those skilled in the art. As shown in FIG. 1, trigger unit 170 accepts the WA signal from 182 (for the trigger timestamp address), the CLK signal from 190 (for fine timestamp of the sample-to-trigger interval), and a trigger input signal, consisting of an analog comparator (not shown) that goes true when the output of 110 crosses a particular threshold voltage. In an alternate embodiment, the trigger event may be generated by a digital block which compares sample codes from ADC 120 to a predetermined threshold.

Write address counter 182 is adapted to free-run so data is acquired and stored circularly (e.g., once the buffer fills to the end, it starts refilling again at the beginning). The write address counter 182 has a known value (“timestamp”) which is stored when a trigger event occurs. A trigger event does not start the acquisition, but rather the trigger identifies a point of interest during the acquisition. The read address counter 184 is loaded with the desired read-start address as soon as a trigger has been received; this address may be earlier or later than the trigger address, depending upon the desired trigger position on or off the visible trace. If later, the readout process must be held off until acquisition has passed that address.

As will be described in more detail below, write address counter 182 and read address counter 184 function simultaneously with the operations of linearizer 140, pre-averager 150 and trace buffer 160 (trace buffer write address counter 186) to continuously acquire data samples for display/processing without ever needing to stop the acquisition. As such, a state machine such as control logic 180 is provided such that DPRAM 130 functions substantially as a first-in-first-out (FIFO) buffer memory or as storage memory where data is read out at the same data rate that it goes into memory. In one example embodiment, a state machine includes an arm state, trigger state, delay state, and re-arm state wherein each state is controlled by the system clock.

In contrast to conventional power sensors or meters, example embodiments of the invention do not halt the data acquisition to allow a microcontroller or DSP unit to catch-up, or employ a decimation process to reduce the sample acquisition rate. Acquisition rate reduction (decimation) may be achieved by reducing the conversion speed of ADC 120 or by reducing the sample write rate of ADC data into DPRAM 130 as controlled by WA counter 182. In other words, example embodiments of the invention provide continuous real-time power processing by a power sensor. Therefore, example embodiments of the present invention provide the benefit of not losing data.

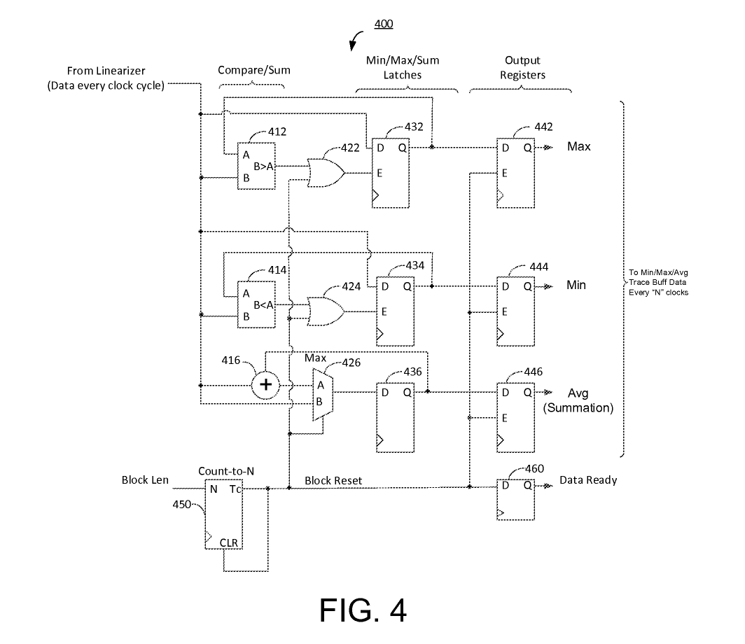

The data samples output from DPRAM 130 are pipelined into a linearizer 140 at full clock speed adapted for converting the stored ADC sample data into calibrated linear (monotonic function of input) power units (e.g., watts, milliwatts and the like) by performing linear interpolation between points stored in one or more look-up-tables, in accordance with example embodiments of the invention as described in more detail below. The linear power units are feed into a trace buffer 160 by way of a pre-averager 150, which reduces the data rate for slower timebases to preserve the “real-time” operation without discarding information (e.g., avoids decimation). For faster timebases (i.e. full clock rate) the pre-averager 150 is merely a pass-through device. A more detailed description of the pre-averager 150 is provided below with reference to FIG. 4.

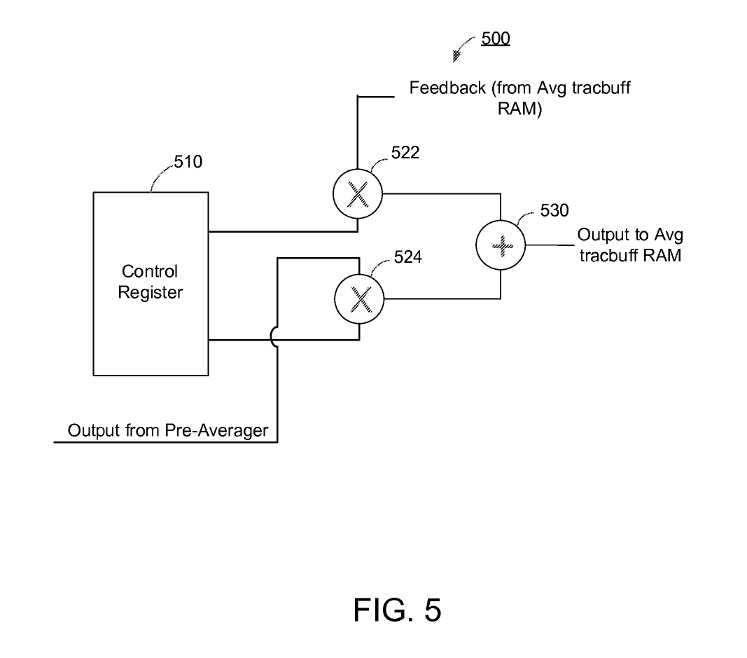

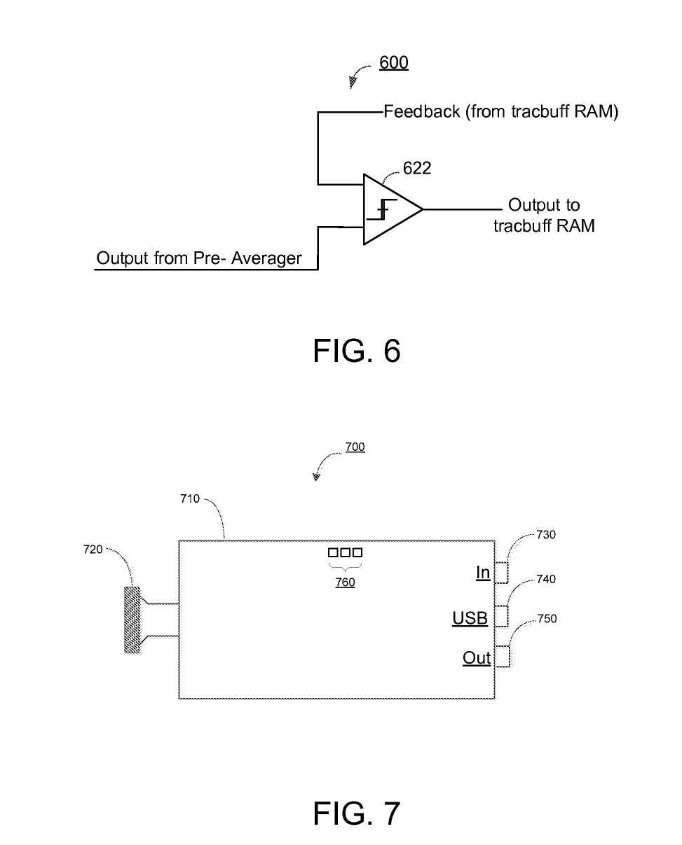

Trace buffer 160 functions as a trigger-synchronized buffer of the desired portion of the data stream (the “sweep”) in DPRAM 130 in accordance with example embodiments of the invention as described in more detail below. The trace buffer 160 includes a plurality of filters 162 which can include an average filter, minimum filter and maximum filter. Also, trace buffer 160 includes a plurality of RAM such as an average trace buffer 164, minimum trace buffer 166 and maximum trace buffer 168. Each trace on a display represents an average or minimum or maximum of N power samples received from Linearizer 140 or the pre-averager 150. The filters perform “sweep averaging,” where an incoming “trace stream” is averaged (or minimum/maximum detected) with existing trace data. This is a trigger-synchronous process, so repetitive events will average to reduce noise or modulation while preserving the portion of the information that is periodic for accurate analysis. The trace buffer provides a time-sequential array of power readings. In an alternative embodiment, a pixel buffer may be implemented in place of trace buffer 160. FIG. 5 and FIG. 6 provide examples of an average trace filter and a minimum/maximum filter suitable for carrying out example embodiments of the invention. It should also be noted that the data samples output from DPRAM 130 or linearizer 140 can also be output for further statistical analysis such as generating a power histogram or a cumulative distribution function (CCDF) curve as known in the art.

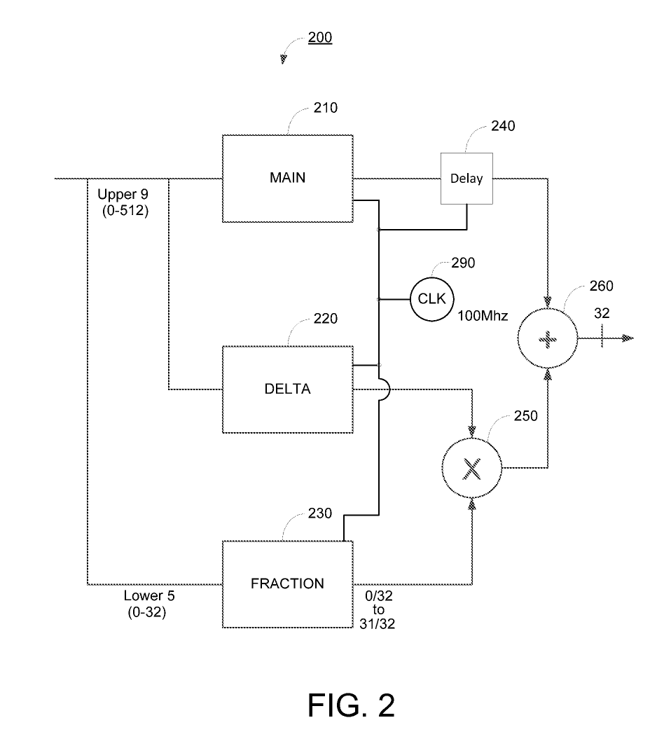

FIG. 2 is a schematic block diagram of a pipelined linearizer for real-time power processing 200 in accordance with example embodiments of the invention. As shown in FIG. 2, a 14 bit data sample from DPRAM 130 (i.e., “ADC code”) is fed into linearizer logic which computes the output power by performing linear interpolation between points stored in one or more look-up-tables. In particular, the linearizer operation takes the 14 bit ADC code having 16,384 possible values and computes the 32 bit floating-point power values into watts from one or more stored tables in one or more memories. As shown in FIG. 2, the 14 bit ADC code word is split in two: (1) an upper 9 bit operation directed to main data buffer 210 and delta data buffer 220; and (2) a lower 5 bit operation directed to the fraction data buffer 230. The main data buffer 210 and delta data buffer 220 are one or more read/write memory (RAM) devices or a field-programmable gate array (FPGA) where each point is stored in logic blocks within the FPGA. The main data buffer 210 contains a look-up table holding 512 points, while the delta table contains a table of values that holds the difference values between points in main data buffer's look-up table as set forth below in Table I. It should be noted that Table I only contains a portion of the full table of possible values by virtue of known numerical relations and methods of reduction of the same as known by those skilled in the arts.

TABLE I
Linearizer Look-up Table for Main and Delta Data Buffers

| Index | Main RAM | Delta RAM |
|---|---|---|
| 0 | 2.6 | 0.1 |
| 1 | 2.7 | 0.2 |
| 2 | 2.9 | 0.25 |
| 3 | 3.15 | 0.3 |
| 4 | 3.45 | 0.3 |
| 5 | 3.75 | 0.35 |
| 6 | 4.1 | 0.4 |
| 7 | 4.5 | 0.5 |
| 8 | 5 | 0 |

Equation No. 1 set forth below provides the relationship between delta values and main values stored in Table I, which are computed by a microprocessor, microcontroller or FPGA and stored in one or more memories.

Delta[i]=Main[i+1]−Main[i] (Equation No. 1)

The fraction data buffer 230 which is a read only memory (ROM) contains a lookup table holding 32 points (e.g., 0/32 to 31/32) as set forth below in Table II. It should be noted that Table II only contains a portion of the full fraction table.

TABLE II
Linearizer Look-up Table for Fraction Data Buffer

| Index | Fraction ROM |
|---|---|
| 0 | 0/32 = 0.00000 |
| 1 | 1/32 = 0.03125 |
| 2 | 2/32 = 0.06250 |
| (3-27) | . . . |
| 28 | 29/32 = 0.87500 |
| 29 | 30/32 = 0.90625 |
| 30 | 31/32 = 0.93750 |

The use of the main data buffer 210, delta data buffer 220 and fraction data buffer 230 enhances the speed of mathematical operations. That is, as mentioned above, the linearizer performs linear interpolation between points in one or more look-up tables. As such, logic operations deployed in the linearizer according to examples embodiments of the invention look up specific values in the main data buffer 210 and the delta data buffer 220, together with coefficient values in the fraction data buffer 230 on each clock cycle of clock 290. That is, the output may be a number of clock cycles behind the input (latency), but data throughput is at full clock rate. The embedded math logic block multiplier 240 multiplies values output from the delta data buffer 220 with coefficient values output from the fraction buffer 230. Then, the result of the multiplier 250 is added with the value output by main data buffer 210 delayed by logic delay 240 by an embedded math logic block, such as adder 260. Delay 240 is adapted to balance the pipeline delay of multiplier 250. The sum is a 32 bit code which is fed into trace buffer 160. The linearizer operation produces an output value in accordance with Equation No. 2 set forth below:

Output value=Main[code/32]+(Delta[code/32]*fraction[code MOD 32]) (Equation No. 2)

An example of operation of the linearizer shown in FIG. 2 is set forth below where the 14 bit ADC value input value is 80. Applying Equation No. 2 resulting in an integer of 2 as a result of dividing 80 by 32 as such the upper nine bits track to index 2 for both the main data buffer 210 and delta data buffer 220. Further, 80 MOD 32 produces an index 16 in fraction data buffer 230 as shown in Table III below.

TABLE III
Example of Operation of Linearizer

| | Index | Memory Value |
|---|---|---|
| Main | 2 | 2.9 |
| Delta | 2 | 0.25 |
| Coefficient | 16 | 0.5 |

Applying the embedded math logic block multiple 250 results in a value of 0.125 (i.e., Delta*Coeff=0.125). Finally, the output values are added by an embedded math logic block adder 260 with the sum of 3.025 which is the output value.

In another example embodiment, the main data buffer 210 contains primary values, and the delta data buffer 220 contains a plurality of “index+1” values which results in a table similar to Table I above. However, the table is shifted down by 1 index. The fraction data buffer would be the same as shown in Table II above. The output value in this embodiment is determined in accordance with equation No. 3 set forth below:

Output value=(Main[code]*Fraction[1.0−code MOD 32])+MOD 32])+(Main[code]*Fraction[code MOD 32]) (Equation No. 3)

In yet another alternative embodiment, both ports of DPRAM 130 are used to look-up Main[1] and Main [i+1] simultaneously, which utilizes less RAM and more mathematical operations, but ties up both ports of DPRAM 130.

In yet another example embodiment, a full 14 bit entry table (16,384) is stored in a single 16k×32 logic block in a FPGA or in one or more RAM. Moreover, the RAM required for carrying out example embodiments of the invention may be increased or reduced depending upon curve-fit accuracy required for the trace buffer described below.

In another example embodiment, the 9 bit/5 bit split of the 14 bit ADC and associations to main data buffer 210, delta data buffer 220 and fraction data buffer 230 (as well as Tables I and Table II) is a 10 bit/4 bit split associated with a 1k/1k/16 entry look-up table to increase resolution. For example, if it is determined that the transfer function representing the power detector and ADC exhibits significant inflection points or spikes, this alternate embodiment would be employed. Alternatively, a transfer function exhibiting a smooth, flat curve requires less memory to accurately characterize the transfer function.

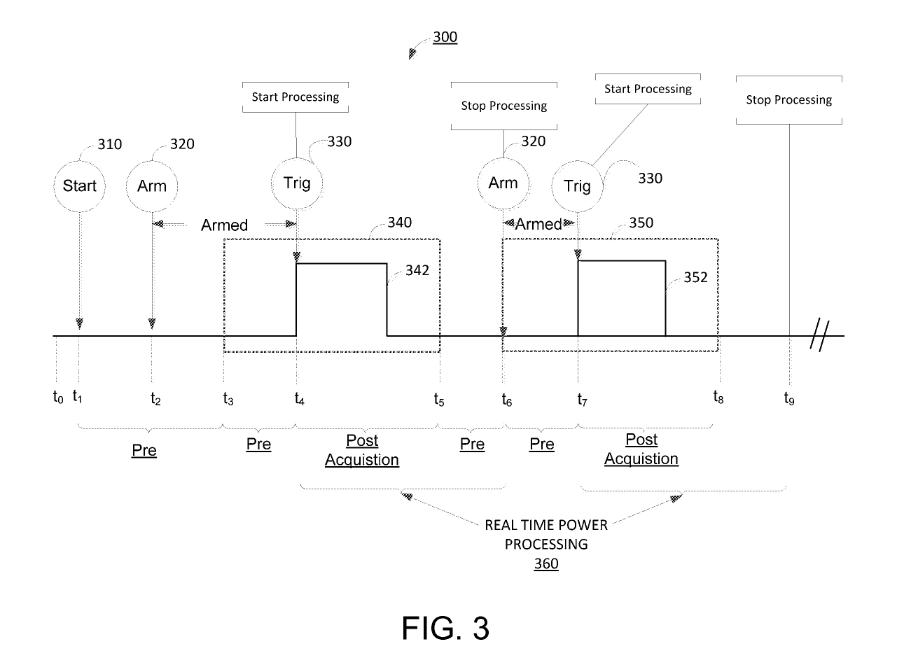

Referring now to FIG. 3, is a timing diagram which illustrates the pipelining processing 300 in accordance with example embodiments of the invention. As shown in FIG. 3, pipelined processing begins with a start acquisition 310 which is activated by a control logic element such as a state machine as shown in FIG. 1. Digital data samples begin storing into a circular buffer such as DPRAM 130 as shown in FIG. 1. Start acquisition 310 is set at t₁ (start of pre-trigger delay time) which is designated in the control logic such that the trigger cannot yet be armed (e.g., until enough pre-trig samples are acquired). During this interval, trigger events are ignored. When the pre-trigger delay time has been satisfied at t₂ Arm 320 is configured in the control logic such that the first subsequent trigger event will trigger the acquisition system (as shown in the t₂ and t₃ intervals). It should also be noted that the time t₁ through t₂ is the pre-trigger delay from Start acquisition 310 to trigger arming. Also, t₃ through t₄ is the delay from trigger arming to start of visible sweep (this interval is zero if the interval from t₁ to t₂ overlap the interval from t₃ to t₄). The interval from t₃ to t₄ is the pre-trigger delay as visible on sweep. Also it should be noted that t₂−t₁=t₄−t₃ (both are identical duration, and may or may not overlap). The “armed” time (t₂ to t₄) is dependent upon the signal. For slow plus repetitive frequency (PRF) signals, this can be quite long, and for fast PRF signals this can approach zero delay. In this fast case, the interval from t₁ to t₂ and the interval from t₃ to t₄ can nearly overlap.

A trigger 330 occurs (e.g., detecting the leading edge of pulse waveform 342) causing timestamp information to be stored while acquisition of data continues. Example embodiments of the present invention provide that processing of data begins immediately after trigger 330 as such sampling is not stopped. Since processing is “real-time” (occurs at same rate as acquisition), the processing interval 360 from t₄ to t₆ is the same as the total acquisition interval from t₃ to t₅. Moreover, since the pre-trigger delay requirements are uniform for all measurement cycles of a given timebase configuration, the end of processing t₆ will coincide with the end of the next measurement cycle's pretrigger delay (t₅ to t₆). Thus, since acquisition 340 never stopped, the pre-trigger interval (t₅ to t₆) will be satisfied at the same instant real-time processing (t₅) completes. Therefore at the end of processing, the pipelined processing immediately arms the trigger for the next sweep by arm 320, waits for a trigger 330 to activate at t₇ the processing data 350 such as pulse waveform 352 is acquired in the process. As shown in FIG. 3, the total time the trigger is not armed (t₄ to t₆) is equal to the acquisition interval (t₃ to t₅). This means the PRF can be as short as the acquisition interval without missing any events.

In an alternative embodiment, real-time processing 360 may include an overhead period, for example the few microseconds to latch the timestamp information, compute values for address counters, and load these values to the FPGA hardware registers. In this embodiment, a dedicated timer may be used to permit re-arming the trigger slightly before the end of real-time processing 360.

In yet another alternate embodiment, the processing and acquisition blocks are duplicated such that a “Ping-Pong” process occurs. This embodiment permits slightly faster operation and allow trace windows to overlap (start of one trace could include data from the end of another). This would be implemented by writing common data to two identical and synchronized sample buffers, and having the read port of each routed to a different processing block.

The benefits of pipeline processing will be appreciated by those skilled in the art. As illustrated in FIGS. 1 and 3, the operation from continuously acquiring and storing the plurality of digitized samples through trace averaging is a sequential operation. This process can be viewed as a series of steps or operations such that each step comprises a signal processing logic block (SPLB) where the output of one SPLB is connected to input of the next SPLB. In other words, each SPLB is connected to or chained to the next SPLB. Pipeline processing refers to an arrangement of SPLBs where each SPLB independently operates on any data it receives during a given clock cycle and then pass its output to the next SPLB in the chain during a given clock cycle; the next SPLB can independently operate on any data it receives during a given clock cycle before passing its output and so on.

Referring now to FIG. 4, a schematic block diagram of a pre-averager processing block configured for real time power processing 400 in accordance with another example embodiment of the present invention. As shown in FIG. 4, linearized, power samples are applied every clock cycle, and the power minimum, power maximum, and power summation of successive blocks of “N” samples is computed every “N” clock cycles, where block length “N” is a computed parameter determined by the ratio of the acquisition frequency to the desired trace buffer display frequency. The power summation may be converted to a power average by scaling the input coefficient of the following average filter block by 1/N.

Block length counter 450 is a “count-to-N” reloadable counter which generates a terminal count (Tc) pulse every N clock cycles. This “Block Reset” pulse serves to reset the counter, transfer the result of the minimum (434), maximum (432) and summation (436) latches to the corresponding output registers (442, 444 and 446), synchronously reset the latches, and signal the following trace buffer filter block that new data is ready via one-clock delay 460.

The minimum (434) and maximum (432) latches are driven by compare blocks (414 and 412, respectively), which will only enable new data to be latched if the incoming data is greater than (412) or less than (414) the existing data held in the latches. New data will also be latched when the Block Reset signal is asserted, as enabled by OR gates 424 and 422 that drive the enable inputs of each latch.

The average latch (436) is driven by an adder (416) which adds the input data to the existing latched summation data, yielding the running summation of input values for the current block. Multiplexer (426), controlled by the Block Reset signal, serves to reset the summation process at the start of each block by selecting the input data for latching rather than the summation result from adder (416).

In an alternate embodiment, two or more of these pre-averager instances (400) may be operated in interleaved fashion to get around long combinatorial delays of the add (416) and compare (414 and 412) blocks. In this case, each pre-averager instance is operated at a lower input data rate, and the outputs of each are merged to produce a single minimum, maximum and summation for the following stage, as should be apparent to those skilled in the art.

Referring next to FIG. 5 depicts a synchronous trace filter adapted for averaging or overwriting trigger-synchronized linearized data currently present in the average trace buffer (164) with trigger-synchronized linearized data from the pre-averager 150 in accordance with example embodiments of the present invention. Synchronous trace filter 500 is disposed in a trace buffer such as trace buffer 160 described above and shown in FIG. 1.

Referring now to FIG. 5, a synchronous trace filter adapted for averaging linearized data is shown in accordance with example embodiments of the invention. As shown in FIG. 5, a control register bank 510 is coupled to two embedded math logic blocks such as a first multiplier 522, and a second multiplier 524. The outputs of the first multiplier 522 and the second multiplier 524 are further coupled to the input of adder 530.

Synchronous trace filtering takes place by multiplying the existing “feedback” value of each trace in an addressed location of trace buffer (150) by one coefficient, and the incoming data from pre-averager block (400) by a second coefficient, then summing the two products, and writing the resulting sum back to the same addressed location in the trace buffer (150). When the sum of the two coefficients is 1.0, those skilled in the art will identify the resulting mathematical function as an IIR filter, where X(tₙ)=(A×Y (tₙ))+(B×X(tₙ₋₁)), where X is the filtered data and Y is the incoming data.

Referring now to FIG. 6, a minimum and maximum buffer of linearized data 600 is shown in accordance with example embodiments of the invention. As shown in FIG. 6, the output value from a linearizer is compared to the feedback from a trace buffer by a comparator 622.

In one non-limiting embodiment, electromagnetic power emanating from RF and microwave communication systems originated from RADAR systems, magnetic resonance imaging (MRI) devices, or particle accelerators. In another non-limiting embodiment, electromagnetic power emanating from RF and microwave communication system include analog signals, including complex digital modulation typically employed in 3G, 4G and evolving 5G cellular communications systems (e.g., CDMA2000, Global system for mobile communications (GSM), general packet radio services (GPRS) and enhanced data for GSM evolution (EDGE), Long term evolution (LTE) and LTE-Advanced, LTE-Beyond (LTE-B), first responder network authority (FirstNet) nationwide network (FNN), wireless local area networks (WiFi) such as WiMAX and IEEE 801.16 as well as microwave communication systems (e.g., direct broadcast satellite (DBS), ancillary terrestrial component (ATC) mobile satellite services (MSS), satellite digital audio radio service (SDARS) or any other telecommunication transmission system employing one or more microwave transmitters). In yet another embodiment, analog signals received by the power detector can represent continuous wave (CW), modulated and pulsed signals suitable for general purpose scalar measurements.

Referring now to FIG. 7 which provides an illustration of a power meter enclosure suitable for hosting the power meter shown in FIG. 1 to FIG. 6 above in accordance with one example embodiment of the invention. As shown in FIG. 7 the power meter enclosure 700 is suitable for providing a small form factor such that it saves valuable rack space and promotes portability. As shown in FIG. 7, the power meter enclosure includes a coaxial connector 720 adapted for receiving RF input on one end of the housing (e.g., a 50 ohm N-type connector). A universal serial bus (USB) 740 is disposed at the other end of the housing, adapted for connecting the power meter to a computer device. Non-limiting examples include a personal computer (PC), laptop computer, tablet, smart phone or any other computing device. In one non-limiting example embodiment, USB 740 is a Type-B USB 2.0 female connector. In another example embodiment, USB 740 can be any type of USB 2.0 or USB 3.0 connector, male or female (e.g., Type A, Type B, Type Mini-A, Type Mini-B, Type Micro-A, and Type Micro-B). In another example embodiment, USB 740 can be any type of commercial-grade USB-A or USB-B male or female suitable for sealed connectivity by way of a threaded coupling or by other means of interlocking USB connectors as known in the art. In yet another embodiment, USB 740 can be replaced by any type of local area network (LAN) eXtensions for Instrumentation (LXI) connectivity together with an external power adapter coupled to the enclosure.

In either embodiment employing USB connectivity, a USB cable can be coupled to USB 740 and can be a length of up to 5.0/6.0 meters (USB 2.0, USB 3.0, respectively) depending on the version of USB employed. Longer lengths are possible if, for example, repeater extension cables and/or CATS extenders for USB, or a USB bridge, is employed as known to those skilled in the art. Moreover, employing USB connectivity in one example embodiment allows multiple USB power meters to be cascaded, employing multiple USB hubs adapted for providing multiple power inputs to a single computer device. Similarly, employing one or more hubs or switches together with LXI connectivity is suitable for allowing multiple USB power meters to be cascaded to provide multiple power inputs to a single computer device.

In another optional embodiment, the power meter enclosure 710 includes a trigger out port 750 and trigger in port 750. For example, the trigger in port 730 can be an SMB connector for a USB sensor employed for coupling power meter 700 to the trigger output of other test equipment (e.g., spectrum analyzer, oscilloscope, or another power meter) or to any other triggering device as known to those skilled in the art. Alternatively, the trigger input port can provide auto level control (ALC) providing a known input signal level used to adjust the RF output level. The trigger out port 750 can be an SMB connector for a USB sensor and adapted to output a plurality of trigger data, wave forms, or other power measurement data including transient phenomena for monitoring or recording to any display or external data recording device as known to those skilled in the art. Power meter enclosure also includes a plurality of LEDs 760 indicates acquisition status, faults or alarm conditions.

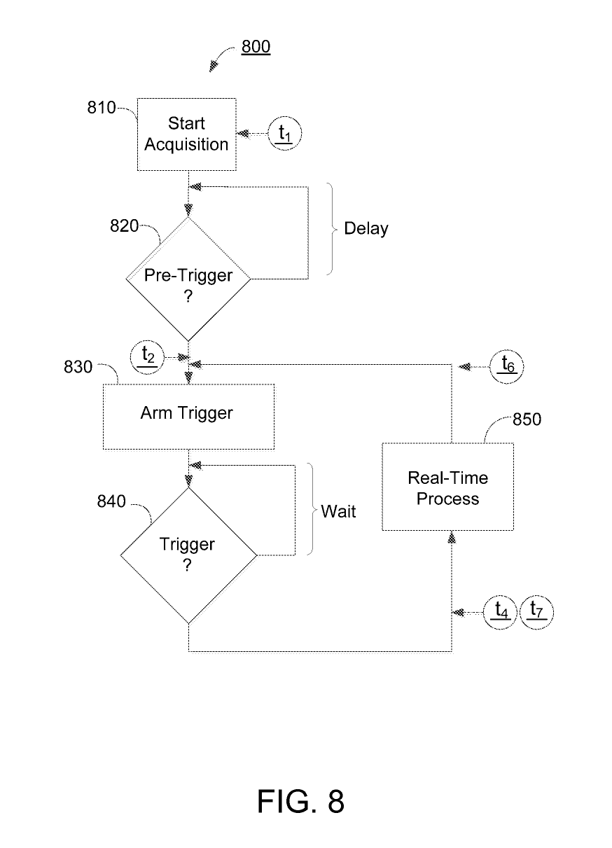

Referring now to FIG. 8 a logical flow diagram of the operation of methods and execution of computer program instructions tangibly embodied on a computer readable memory or field programmable gate array is shown 800 adapted to provide real-time power processing in accordance with example embodiments of the present invention. As shown in FIG. 8 (and FIG. 3), pipelined processing begins with a start acquisition 810 which is activated by a control logic element such as a state machine as shown in FIG. 1. Digital data samples begin storing into a circular buffer such as DPRAM 130 as shown in FIG. 1. Start acquisition 810 is set at t₁ (start of pre-trigger delay time) which is designated in the control logic such that the trigger cannot yet be armed (e.g., until enough pre-trigger 820 samples are acquired). During this interval, trigger events are ignored. When the pre-trigger delay 820 has been satisfied, arm event 830 is configured in the control logic such that the first trigger event will trigger the acquisition system (as shown in the t₂ and t₃ intervals). It should also be noted that the time t₁ is the pre-trigger (820) delay from Start acquisition 810 to trigger arming 830. Also, t₂ is the delay from trigger arming to start of visible sweep (this interval is zero if the interval from t₁ to t₂ overlap the interval from t₃ to t₄). The interval from t₃ to t₄ is the pre-trigger delay 830 as visible on sweep. Also it should be noted that t₂−t₁=t₄−t₃ (both are identical duration, and may or may not overlap). The “armed” time (t₂ to t₄) is dependent upon the signal. For slow pulse repetition frequency (PRF) signals, this can be quite long, and for fast PRF signals this can approach zero delay. In this fast case, the interval from t₁ to t₂ and the interval from t₃ to t₄ can nearly overlap.

A trigger 840 occurs (e.g., detecting the leading edge of pulse waveform) causing timestamp information to be stored while acquisition of data continues. Example embodiments of the present invention provide that processing of data begins immediately after trigger 840 as such sampling is not stopped. Since processing is “real-time” (occurs at a rate no less than acquisition), the processing interval from t₄ to t₆ (850) is the same duration as the total acquisition interval from t₃ to t₅. Moreover, since the pre-trigger delay requirements (820) are uniform for all measurement cycles of a given timebase configuration, the end of processing t₆ will coincide with the end of the next measurement cycle's pretrigger delay (t₅ to t₆). Thus, since acquisition 340 never stopped, the pre-trigger interval (t₅ to t₆) will be satisfied at the same instant real-time processing (t₅) completes. The arm trigger 830 and trigger 840 comprise the real-time processing 850. The post data trigger acquisition is active from trigger 840 at t₄ and immediately followed by the next sweep's pretrigger interval 820. Therefore at the end of processing 850, the pipelined processing immediately arms the trigger (830), then waits for the next trigger to activate further real-time processing of data.

Example embodiments of the invention provide a method, comprising, receiving an electromagnetic signal by a power detector, converting the received electromagnetic signal into a plurality of digitized samples, continuously acquiring and storing the plurality of digitized samples of into one or more sample memory buffers based upon a plurality of power processing events, simultaneously reading out of the one or more sample memory buffers by pipeline-processing the stored plurality of digitized samples, linearizing the plurality of digitized samples, wherein linearizing comprises converting the plurality of digitized samples into a plurality of linear power units such that the linear power units represent power measurements based upon the plurality of power processing events, and trace averaging the plurality of linear power units, wherein simultaneously reading out of the one or more sample memory buffers, linearizing, and trace averaging are pipeline processed.

In one aspect of the invention, the plurality of power processing events are executed by a state machine, the power processing events selected from the group consisting of an arm event, a trigger event, a delay event, and a re-arm event.

In another aspect of the invention, the plurality of linear power units are pre-averaged to reduce the data rate based upon the plurality of the power processing events, wherein the plurality of linear power units are pipeline processed into a pre-averager and wherein the pre-averaged linear power units are pipeline processed into a trace buffer.

In another aspect of the invention, one or more sample memory buffers function substantially as a first-in-first-out memory (FIFO) buffer.

In another aspect of the invention, a rate of digitized sample readout and pipeline processing matches or exceeds a rate of digitized sample acquisition to provide continuous gap-free signal acquisition.

In yet aspect of the invention, one or more sample memory buffers provide a look-back period adapted to store pre-trigger information for further processing of the digitized samples.

In another aspect of the invention, the pipeline-processing comprises one or more parallel lanes of pipelined logic.

In yet another aspect of the invention, the digitized samples are converted into the plurality of linear power points by performing linear interpolation between points stored in one or more look up tables.

In another embodiment of the invention, the electromagnetic signal emanates from an RF or microwave communication systems selected from the group consisting of a RADAR system, a magnetic resonating image (MRI) device, or a particle accelerator.

In yet another embodiment of the invention, the electromagnetic signal emanates from an RF or microwave communication systems, including complex digital modulation employed in a cellular communications system, selected from the group consisting of a code division multiple access 2000 system, a global system for mobile communications (GSM) system, a general packet radio services system, an enhanced data for GSM evolution system, a long term evolution (LTE) system, a LTE-Advanced system, a LTE-Beyond system, or a first responder network authority nationwide network.

In another embodiment of the invention, the electromagnetic signal emanates from an RF or microwave communication systems, including complex digital modulation employed in a wireless communications system, selected from the group consisting of wireless local area networks, a worldwide interoperability for microwave access system, or an Institute of Electrical and Electronics Engineers (IEEE) 801.16 system.

In yet another embodiment of the invention, the electromagnetic signal emanates from an RF or microwave communication systems, including complex digital modulation employed in a microwave communications system, selected from the group consisting of a direct broadcast satellite system, an ancillary terrestrial component mobile satellite services system, a satellite digital audio radio service system, or a telecommunication transmission system employing one or more microwave transmitters.

In a further aspect of the invention, the method further comprising the step of pre-averaging a successive block of linearized power samples to yield average, minimum, and maximum power values at a reduced data rate.

In yet another embodiment, an apparatus is provided comprising a power detector, an Analog-to-Digital Converter (ADC) having an input for receiving an electromagnetic signal and an output providing a plurality of digitized samples of the electromagnetic signal, at least one Programmable Logic Device (PLD), at least one memory storing a configuration instruction, wherein the at least one memory storing the configuration instruction is configured with at least one set of logic to cause the power sensing apparatus to acquire the electromagnetic signal by the power detector and continuously acquire and store the plurality of digitized samples into one or more memory buffers based upon a plurality of power processing events, a linearizer configured to simultaneously read out of memory by pipeline-processing the plurality of digitized samples, wherein the linearizer by pipeline processing converts the digitized samples into a plurality of linear power units by performing linear interpolation between one or more look-up-tables based on the plurality of processing events, and a trace buffer, wherein the trace buffer comprises a plurality of filters configured to perform sweep averaging.

In one aspect of this embodiment, the Programmable Logic Device (PLD) is selected from the group consisting of a Field Programmable Gate Array (FPGA) or a Complex Programmable Logic Device (CPLD).

In another aspect of this embodiment, the at least one memory storing a configuration instruction is internal to the at least one Programmable Logic Device (PLD).

In another aspect of this embodiment, the apparatus further comprises a pre-averager configured to receive the plurality of linear power units at an input data rate and provide an output data rate, wherein the output data rate is reduced 1/N where N is the programmed block length such that when N equals one the output data rate matches the input data rate.

In another aspect of this embodiment, the plurality of filters in the trace buffer are configured for averaging or overwriting trigger-synchronized linear power units currently stored in the trace buffer with trigger-synchronized linear power units from the pre-averager.

In another aspect of this embodiment, the pipeline-processing comprises one or more parallel lanes of pipelined logic.

In another aspect of this embodiment, the rate of digitized sample readout and pipeline processing matches or exceeds a rate of digitized sample acquisition.

In still another aspect of this embodiment, the programmable logic device is remotely connected to the analog-to-digital converter by a cable, and in another alternative embodiment the analog-to-digital converter is co-located with the programmable logic device but remotely connected to the to the power detector.

In another aspect of this embodiment, the power sensing apparatus is a universal serial bus (USB) power sensor.

In another embodiment, a program storage device readable by a machine, tangibly embodying a program of instructions executable by the machine for causing to the machine to perform operations, the operations comprising: receiving an electromagnetic signal by a power detector, converting the received electromagnetic signal into a plurality of digitized samples, continuously acquiring and storing a plurality of digitized samples into one or more sample memory buffers based upon a plurality of power processing events, simultaneously reading out of memory the stored plurality of digitized samples, linearizing the plurality of digitized samples, wherein linearizing comprises converting the digitized samples into a plurality of linear power units such that the plurality of linear power units represent power measurements based upon the plurality of power processing events, and trace averaging the plurality of linear power units, wherein the simultaneously reading out of the one or more sample memory buffers, linearizing the digitized samples, and trace averaging are pipeline processed.

In another aspect of this embodiment, the program storage device further comprises the step of pre-averaging the plurality of digitized samples to reduce the data rate based upon the plurality of the power processing events, wherein the linearized digitized samples are pipeline processed into a pre-averager and wherein the pre-averaged digitized samples are pipeline processed into a trace buffer.

As used in this application, the term ‘circuitry’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and (c) circuits, such as a microprocessor(s) or a portion of a microprocessor(s), that require software or firmware for operation, even if the software or firmware is not physically present. This definition of ‘circuitry’ applies to all uses of the term in this application, including in any claims. As a further example, as used in this application, the term “circuitry” would also cover an implementation of merely a processor (or multiple processors) or portion of a processor and its (or their) accompanying software and/or firmware. The term “circuitry” also would cover, if applicable to the particular claim element, a baseband integrated circuit, or applications processor integrated circuit, for a mobile phone or a similar integrated circuit in server, a cellular network device, or other network device.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

The foregoing description should therefore be considered as merely illustrative of the principles, teachings and example embodiments of this invention, and not in limitation thereof.

Further, some of the various features of the above non-limiting embodiments may be used to advantage without the corresponding use of other described features. While the invention has been described in conjunction with specific embodiments, one of ordinary skill in the art appreciates that there are many variations that are in accordance with the foregoing description and remain within the scope of the appended claim set. All of the features described above or shown in the drawings can be advantageously combined with one another within the framework of the invention. Accordingly, it is intended that the present invention embrace all such alternatives, modifications and variations as fall within the scope of the appended claims.

The invention claimed is:

1. A method for measuring power of an electromagnetic signal, the method comprising:
receiving the electromagnetic signal by a power detector;
converting the received electromagnetic signal into a plurality of digitized samples;
continuously acquiring and storing the plurality of digitized samples into one or more sample memory buffers based upon a plurality of power processing events;
simultaneously reading out of the one or more sample memory buffers the stored plurality of digitized samples;
linearizing the plurality of digitized samples, wherein linearizing comprises converting the digitized samples into a plurality of linear power units such that the plurality of linear power units represent power measurements based upon the plurality of power processing events; and
trace averaging the plurality of linear power units, wherein the simultaneously reading out of the one or more sample memory buffers, linearizing, and trace averaging are pipeline processed.

2. The method of claim 1, wherein the plurality of power processing events are executed by a state machine, the power processing events selected from the group consisting of:
an arm event,
a trigger event,
a delay event, and
a re-arm event.

3. The method of claim 2, further comprising the step of:
pre-averaging the plurality of linear power units to reduce the data rate based upon the plurality of power processing events, wherein the plurality of linear power units are pipeline processed into a pre-averager and wherein the pre-averaged linear power units are pipeline processed into a trace buffer.

4. The method of claim 1, wherein the one or more sample memory buffers function substantially as a first-in-first-out memory (FIFO) buffer.

5. The method of claim 1, wherein the one or more sample memory buffers provide a look-back period adapted to store pre-trigger information for further processing of the digitized samples.

6. The method of claim 1, wherein a rate of digitized sample readout and pipeline processing matches or exceeds a rate of digitized sample acquisition.

7. The method of claim 6, wherein the rate of digitized sample readout and pipeline processing matching or exceeding the rate of digitized sample acquisition provides continuous gap-free signal acquisition.

8. The method of claim 1, wherein the pipeline-processing comprises one or more parallel lanes of pipelined logic.

9. The method of claim 1, wherein the digitized samples are converted into the plurality of linear power points by performing linear interpolation between points stored in one or more look up tables.

10. The method of claim 3, further comprising the step of:
pre-averaging a successive block of linearized power samples to yield average, minimum, and maximum power values at a reduced data rate.

11. The method of claim 1, wherein the electromagnetic signal emanates from a Radio Frequency (RF) or Microwave communications device.

12. The method of claim 1, wherein the electromagnetic signal emanates from an electromagnetic radiator selected from the group consisting of:
a RADAR system,
a magnetic resonating image (MRI) device, or
a particle accelerator.

13. A power sensing apparatus, comprising:
a power detector;
an Analog-to-Digital Converter (ADC) having an input for receiving an electromagnetic signal and an output providing a plurality of digitized samples of the electromagnetic signal;
at least one Programmable Logic Device (PLD);
at least one memory storing a configuration instruction, wherein the at least one memory storing the configuration instruction is configured with at least one set of logic to cause the power sensing apparatus to acquire the electromagnetic signal by the power detector and continuously acquire and store the plurality of digitized samples into one or more memory buffers based upon a plurality of power processing events;
a linearizer configured to simultaneously read out of memory by pipeline-processing the plurality of digitized samples, wherein the linearizer by pipeline processing converts the digitized samples into a plurality of linear power units by performing linear interpolation between points in one or more look-up-tables based on the plurality of processing events; and
a trace buffer, wherein the trace buffer comprises a plurality of filters configured to perform sweep averaging.

14. The power sensing apparatus of claim 13, wherein the Programmable Logic Device (PLD) is selected from the group consisting of:
a Field Programmable Gate Array (FPGA), or
a Complex Programmable Logic Device (CPLD).

15. The power sensing apparatus of claim 14, wherein the at least one memory storing a configuration instruction is internal to the at least one Programmable Logic Device (PLD).

16. The power sensing apparatus of claim 13, further comprising:
a pre-averager, wherein the pre-averager is configured to receive the plurality of linear power units at an input data rate and provide an output data rate, wherein the output data rate is reduced by 1/N such that when N equals one the output data rate matches the input data rate.

17. The power sensing apparatus of claim 16, wherein the plurality of filters in the trace buffer are configured for averaging or overwriting trigger-synchronized linear power units currently stored in the trace buffer with trigger-synchronized linear power units from the pre-averager.

18. The power sensing apparatus of claim 13, wherein pipeline-processing comprises one or more parallel lanes of pipelined logic.

19. The power sensing apparatus of claim 13, wherein a rate of digitized sample readout and pipeline processing matches or exceeds a rate of digitized sample acquisition.

20. The power sensing apparatus of claim 14, wherein the programmable logic device is remotely connected to the analog-to-digital converter by a cable.

21. The power sensing apparatus of claim 14, wherein the analog-to-digital converter is remotely connected to the power detector by a cable.

22. The power sensing apparatus of claim 13, wherein the power sensing apparatus is a universal serial bus (USB) power sensor.

23. A program storage device readable by a machine, tangibly embodying a program of instructions executable by the machine for causing to it perform operations, the operations comprising:
receiving the electromagnetic signal by a power detector;
converting the received electromagnetic signal into a plurality of digitized samples;
continuously acquiring and storing the plurality of digitized samples into one or more sample memory buffers based upon a plurality of power processing events;
simultaneously reading out of the one or more sample memory buffers the stored plurality of digitized samples;
linearizing the plurality of digitized samples, wherein linearizing comprises converting the digitized samples into a plurality of linear power units such that the plurality of linear power units represent power measurements based upon the plurality of power processing events; and
trace averaging the plurality of linear power units, wherein the simultaneously reading out of the one or more sample memory buffers, linearizing the digitized samples, and trace averaging are pipeline processed.

24. The program storage device of claim 23, further comprising the step of:
pre-averaging the plurality of digitized samples to reduce the data rate based upon the plurality of the power processing events, wherein the linearized digitized samples are pipeline processed into a pre-averager and wherein the pre-averaged digitized samples are pipeline processed into a trace buffer.
